(19) United States
(12) Patent Application Publication
(10) Pub. No.: US 2025/0337284 A1
(43) Pub. Date: Oct. 30, 2025

(54) METHOD FOR POWER LOSS ACCOUNTING

(71) Applicant: BH EVS Co., Ltd., Seoul (KR)

(72) Inventors: Kyung Hwan KIM, Seoul (KR); Hyeong Geol KWAK, Incheon (KR); Yong Cheol PARK, Gwacheon-si Gyeonggi-do (KR); Seong Hun LEE, Seoul (KR)

(73) Assignee: BH EVS Co., Ltd., Seoul (KR)

(21) Appl. No.: 19/257,626

(22) Filed: Jul. 2, 2025

Related U.S. Application Data
(63) Continuation of application No. PCT/KR2024/000192, filed on Jan. 4, 2024.

(30) Foreign Application Priority Data
Jan. 4, 2023 (KR) 10-2023-0001457
Feb. 27, 2023 (KR) 10-2023-0026376

(51) Int. Cl. H02J 50/80; H02J 50/10; H02J 50/60

(52) U.S. Cl. CPC H02J 50/80; H02J 50/10; H02J 50/60

(57) ABSTRACT

Provided is a method for power loss accounting. The method includes the steps of: acquiring information on at least one of the distance between a wireless power transmitter and a wireless power receiver and a rectified voltage of the wireless power receiver; and estimating power loss due to friendly metal with reference to the acquired information.

### CROSS-REFERENCE TO RELATED APPLICATIONS

This application is a continuation of International Application No. PCT/KR2024/000192 filed on Jan. 4, 2024, which claims priority to Korean Patent Application No. 10-2023-0001457 filed on Jan. 4, 2023, and Korean Patent Application No. 10-2023-0026376 filed on Feb. 27, 2023, the entire contents of which are herein incorporated by reference.

### FIELD OF THE INVENTION

The present invention relates to a method for power loss accounting.

### BACKGROUND

The Wireless Power Consortium (WPC) is an international standardization body in the field of wireless power transmission, responsible for establishing the Qi standard for inductive wireless charging. The Qi standard primarily defines the Baseline Power Profile (BPP) and Extended Power Profile (EPP), with the Magnetic Power Profile (MPP) recently introduced as a new addition.

For inductive wireless charging, a wireless power transmitter and a wireless power receiver are basically required, and it is essential that no foreign objects (FO) exist between the transmitter and receiver. If a foreign object is present between them, not only will charging performance degrade, but serious safety risks may also arise.

The Qi standard specifies various Foreign Object Detection (FOD) methods based on BPP and EPP, while the MPP Power Loss Accounting (MPLA) method is currently under discussion with respect to MPP-based FOD methods.

If we refer to the MPLA method currently under discussion as a conventional MPLA method, this requires estimating power loss caused by friendly metal (FM) in order to estimate (or account for) power loss due to foreign objects. However, the linear model (i.e., linear fit curve) for power loss due to FM derived by the conventional MPLA method shows significant deviation from reality. This leads to substantial errors when estimating power loss due to FM in practical applications, directly resulting in degraded performance of the FOD methods.

### SUMMARY OF THE INVENTION

One object of the present invention is to solve all the above-described problems in the prior art.

Another object of the invention is to propose an improved MPLA method based on the analysis of physical causes that lead to errors when estimating power loss due to FM using a conventional MPLA method.

The representative configurations of the invention to achieve the above objects are described below.

According to one aspect of the invention, there is provided a method for power loss accounting, the method comprising the steps of: acquiring information on at least one of a distance between a wireless power transmitter and a wireless power receiver and a rectified voltage of the wireless power receiver; and estimating power loss due to friendly metal with reference to the acquired information.

According to another aspect of the invention, there is provided a wireless power transmitter, comprising: an acquisition unit configured to acquire information on at least one of a distance between the wireless power transmitter and a wireless power receiver and a rectified voltage of the wireless power receiver; and an estimation management unit configured to estimate power loss due to friendly metal with reference to the acquired information.

According to yet another aspect of the invention, there is provided a method for power loss accounting, the method comprising the steps of: acquiring information on at least one of a distance between a wireless power transmitter and a wireless power receiver and a rectified voltage of the wireless power receiver; and causing power loss due to friendly metal to be estimated with reference to the acquired information.

According to still another aspect of the invention, there is provided a wireless power receiver, comprising: an acquisition unit configured to acquire information on at least one of a distance between a wireless power transmitter and the wireless power receiver and a rectified voltage of the wireless power receiver; and an estimation management unit configured to cause power loss due to friendly metal to be estimated with reference to the acquired information.

In addition, there are further provided other methods, wireless power transmitters, and wireless power receivers to implement the invention.

According to the invention, the improved MPLA method may demonstrate superior RMSE (Root Mean Squared Error) performance compared to the conventional MPLA method, and may enhance FOD performance when implemented in MPP-based wireless power transmitters and receivers.

### BRIEF DESCRIPTION OF THE DRAWINGS

FIG. 1 shows a loss-split model for a wireless power transmitters and a wireless power receiver.

FIGS. 2A, 2B and 2C show linear models derived by a conventional MPLA method.

FIG. 3 shows deviation observed in a linear model for power loss due to FM derived by the conventional MPLA method.

FIGS. 4A, 4B, 5A, 5B, 6A, 6B, 7A, and 7B schematically show components of the wireless power transmitter and wireless power receiver.

FIG. 8 shows how to derive a linear model for power loss due to FM using the conventional MPLA method.

FIG. 9 shows how to derive a linear model for power loss due to FM using an improved MPLA method.

FIG. 10 shows the linear model for power loss due to FM derived by the improved MPLA method.

FIG. 11 shows linear models derived by the conventional MPLA method under GG, TG, and GR conditions.

FIG. 12 shows linear models for power loss due to FM derived by the conventional MPLA method under a TR condition.

FIG. 13 shows linear models for power loss due to FM derived by the improved MPLA method under GG, TG, and GR conditions.

FIG. 14 shows linear models for power loss due to FM derived by the improved MPLA method under a TR condition.

### DETAILED DESCRIPTION

In the following detailed description of the present invention, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different from each other, are not necessarily mutually exclusive. For example, specific shapes, structures and characteristics described herein may be implemented as modified from one embodiment to another without departing from the spirit and scope of the invention. Furthermore, it shall be understood that the positions or arrangements of individual elements within each embodiment may also be modified without departing from the spirit and scope of the invention. Therefore, the following detailed description is not to be taken in a limiting sense, and the scope of the invention is to be taken as encompassing the scope of the appended claims and all equivalents thereof. In the drawings, like reference numerals refer to the same or similar elements throughout the several views.

The term “estimating” herein may be used interchangeably with terms such as “accounting for,” “calculating,” or “measuring” in some cases, and vice versa.

Hereinafter, various preferred embodiments of the invention will be described in detail with reference to the accompanying drawings to enable those skilled in the art to easily implement the invention.

### Background of Proposal of the Improved MPLA Method

MPP is a power profile newly introduced in the Qi2 standard, with discussions starting based on Apple's MagSafe. Compared to the existing BPP and EPP, MPP is characterized by the inclusion of an additional element, i.e., a magnet that aligns and fixes a wireless power transmitter (hereinafter, “transmitter” or “PTx”) and a wireless power receiver (hereinafter, “receiver” or “PRx”).

As discussed in the background section, establishing an FOD (Foreign Object Detection) method is very important for MPP as well as for BPP and EPP. The conventional MPLA method, which is discussed as an FOD method for MPP, is planned to be implemented as follows.

In the conventional MPLA method, power loss due to foreign objects Pro is estimated as a difference between transmitted power PPT and received power PPR. In other words, a relationship equation P_{FO}=P_{PT}−P_{PR} holds. Here, P_{PT} is estimated by the transmitter through a relationship equation P_{PT}=V_{IN}I_{IN}−(P_{circuit loss, Tx}+P_{coil loss,Tx}+P_{FM}), and P_{PR} is estimated by the receiver through a relationship equation P_{PR}=V_{RECT}I_{RECT}+P_{circuit loss,Rx}+P_{coil loss,Rx}. That is, in order to estimate P_{FO}, the transmitter should estimate an input voltage V_{IN}, input current I_{IN}, transmitter-side circuit power loss P_{circuit loss,Tx}, transmitter-side coil power loss P_{coil loss,Tx}, and power loss due to friendly metal P_{FM}. Further, the receiver should estimate a rectified voltage V_{RECT}, rectified current/RECT, receiver-side circuit power loss P_{circuit loss,Rx}, and receiver-side coil power loss Pcoil loss, Rx. Under a TR condition (details of which will be described later), P_{coil loss,Tx}, P_{coil loss, Rx}, and P_{FM} are estimated through relationship equations P_{coil loss,Tx}=g_{coil,Tx} b_{coil} R_{coil air,Tx} I_{TX}², P_{coil loss,Rx}=g_{coil,Rx} m_{coil} R_{coil air,Rx} I_{RECT}², and P_{FM}≤g_{FM} α_{FM} I_{Tx}²+g_{FM,DC} α_{FM,DC}, respectively. Here, b_{coil}, m_{coil}, α_{FM}, and α_{FM,DC} may be referred to as MPLA coefficients or PLA coefficients, and g_{coil,Tx}, g_{coil,Rx}, g_{FM}, and g_{FM,DC} may be referred to as scaling factors or ecosystem scaling factors.

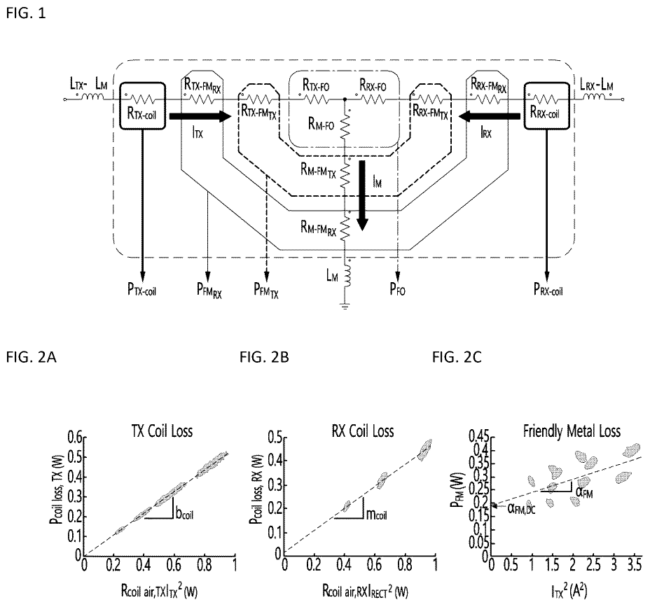

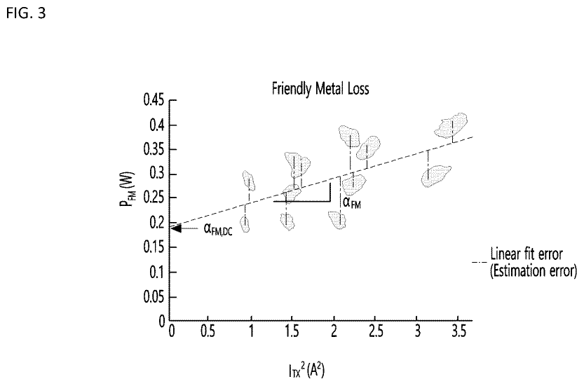

A loss-split model for the transmitter and receiver as shown in FIG. 1 is used to derive linear models (i.e., linear fit curves) as shown in FIGS. 2A, 2B and 2C, and then the MPLA coefficients are calculated from the slopes and intercepts of the curves.

The scaling factors are defined as

$${g}_{coil , Tx} = {b}_{coil}^{GR} / {b}_{coil}^{GG} \approx {b}_{coil}^{TR} / {b}_{coil}^{TG} , {g}_{coil , Rx} = {m}_{coil}^{GR} / {m}_{coil}^{GG} \approx {m}_{coil}^{TR} / {m}_{coil}^{TG} ,$$

$${g}_{FM} = {α}_{FM}^{TG} / {α}_{FM}^{GG} \approx {α}_{FM}^{TR} / {α}_{FM}^{GR} , and$$

$${g}_{FM , DC} = {α}_{FM , DC}^{TG} / {α}_{FM , DC}^{GG} \approx {α}_{FM , DC}^{TG} / {α}_{FM , DC}^{GG} ,$$

respectively. Here, superscripts GG, TG, GR, and TR are used to distinguish various transmitter/receiver pairs. Specifically, GG refers to the case where the transmitter is a reference transmitter defined by the Qi standard (Ref. PTx (TPT)) and the receiver is also a reference receiver defined by the Qi standard (Ref. PRx (TPR)). TG refers to the case where the transmitter is a general (or unknown) transmitter (General PTx) and the receiver is a reference receiver defined by the Qi standard (Ref. PRx (TPR)). GR refers to the case where the transmitter is a reference transmitter defined by the Qi standard (Ref. PTx (TPT)) and the receiver is a general (or unknown) receiver (General PRx). TR refers to the case where the transmitter is a general (or unknown) transmitter (General PTx) and the receiver is also a general (or unknown) receiver (General PRx). The conventional MPLA method ultimately aims to derive results under a TR condition, and the improved MPLA method to be described later follows the same goal.

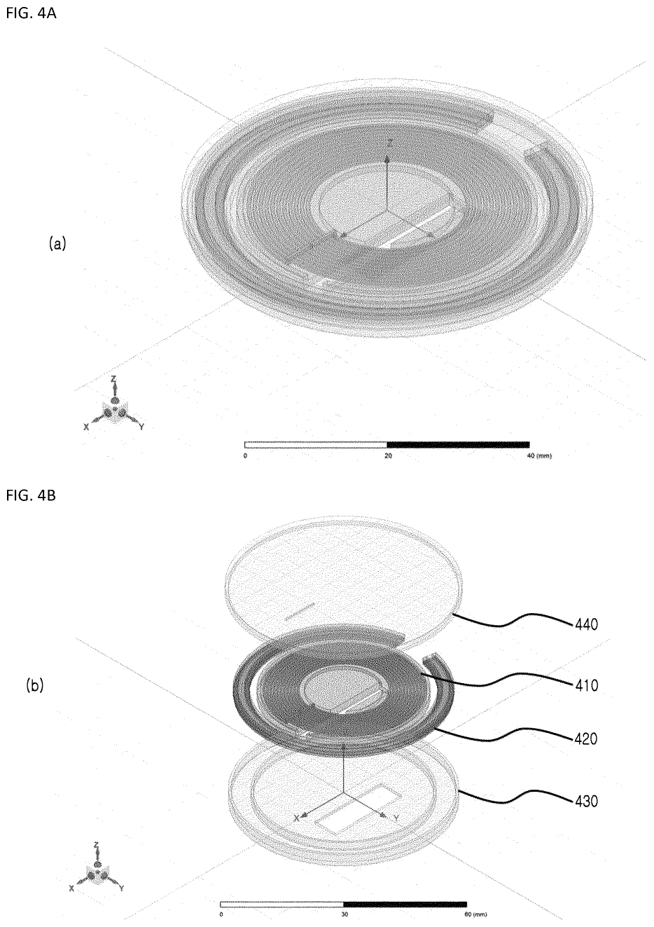

In the conventional MPLA method, a linear model for P_{FM} (see FIG. 2C) shows greater deviation compared to a linear model for P_{coil loss,Tx} (see FIG. 2A) or a linear model for P_{coil loss,Rx} (see FIG. 2B). FIG. 3 specifically shows the deviation. This causes significant errors when estimating P_{FM} in practical applications, which directly leads to degradation in the performance of the FOD method.

As discussed earlier, in the conventional MPLA method, power loss due to friendly metal P_{FM} is estimated as the relationship equation P_{FM}≈g_{FM} α_{FM} I_{Tx}²+g_{FM,DC} α_{FM,DC}. Here, the friendly metal may refer to metal components included in the receiver. According to this relationship equation, the conventional MPLA method estimates P_{FM} solely as a function of I_{Tx}² (here, I_{Tx} is a coil current on the transmitter side), which is presumed to be the cause of the deviation.

In addition to I_{Tx}² (or I_{Tx}), the improved MPLA method proposed in the invention may allow at least one of a distance between the transmitter and receiver (z or z-distance) and the rectified voltage of the receiver V_{RECT} to function as a variable for estimating P_{FM}.

First, regarding the influence of the z-distance on P_{FM}, leakage magnetic flux increases and interacts with a wider area of friendly metal as the z-distance increases. This phenomenon inevitably causes changes in P_{FM} even under the same/Tx conditions.

Next, regarding the influence of V_{RECT} On P_{FM}, V_{RECT} may change instantaneously in a certain range of I_{RECT} (e.g., from 12V to 14V), causing discontinuities in I_{M}. I_{M} is the sum of the transmitter-side coil current I_{Tx} and receiver-side coil current I_{Rx} in the loss-split model shown in FIG. 1. Because the influence of I_{M} on P_{FM} is dominant, changes in V_{RECT} inevitably cause discontinuities in P_{FM}.

According to this physical cause analysis, the z-distance and V_{RECT}, along with I_{Tx}, should be considered as core variables influencing P_{FM}. Based on this insight, while the conventional MPLA method does not consider the z-distance and V_{RECT} as variables for P_{FM}, the improved MPLA method proposed in the invention considers at least one of the z-distance and V_{RECT} as variables for P_{FM}.

### Improved MPLA Method

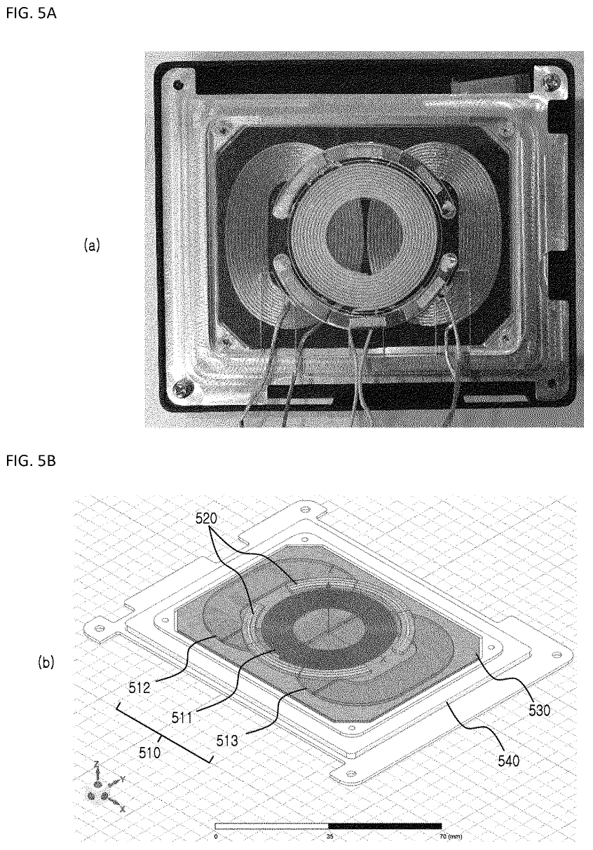

According to one embodiment of the invention, the transmitter and receiver may include basic configurations for wireless charging by magnetic induction, such as a coil module, and a magnet may be additionally included in the transmitter for MPP applications. Further, the receiver may include friendly metal. The configurations of the transmitter and receiver are shown in FIGS. 4 to 7.

Specifically, FIGS. 4A and 4B show a perspective view and an exploded perspective view of a reference transmitter (Ref. PTx (TPT)) defined by the Qi standard, respectively. As shown in FIGS. 4A and 4B, the transmitter may include a coil 410, a magnet 420, a lower enclosure 430, and an upper enclosure 440. Here, the coil 410 may be configured to operate on the basis of MPP, and the magnet 420 may be formed to at least partially surround the coil 410.

Further, FIGS. 5A and 5B show a plan view and a perspective view of a general (or unknown) transmitter (General PTx), respectively. Unlike the perspective view, the plan view shows a prototype rather than a modeled drawing. As shown in FIGS. 5A and 5B, the transmitter may include a coil 510, a magnet 520, ferrite 530, and a bracket 540. Specifically, the coil 510 may consist of one coil 511 disposed at the upper part and two coils 512, 513 disposed at the lower part, and the upper coil 511 may be configured to operate on the basis of MPP. Further, the magnet 520 may be formed to at least partially surround the upper coil 511. For example, the magnet 520 may basically have a circular shape, with arcs having a central angle of 150 degrees alternatingly arranged. The bracket 540 may be made of aluminum. Meanwhile, in the transmitter, the distance from the upper coil 511 to the upper surface of the transmitter may be 1.2 mm, and the distance from the magnet (520) to the upper surface of the transmitter may be 0.9 mm.

Further, FIGS. 6A and 6B show a perspective view and an exploded perspective view of a reference receiver (Ref. PRx (TPR)) defined by the Qi standard, respectively. As shown in FIGS. 6A and 6B, the receiver may include a coil 610, a magnet 620, a lower enclosure 630, a support plate 640, and friendly metal 650. Here, the coil 610 may operate on the basis of MPP, and the magnet 620 may be formed to at least partially surround the coil 610. The thickness of the friendly metal 650 may be 4.3 mm.

Further, FIGS. 7A and 7B show a perspective view and an exploded perspective view of a general (or unknown) receiver (General PRx), respectively. As shown in FIGS. 7A and 7B, the receiver may include a coil 710, a magnet 720, a lower enclosure 730, a support plate 740, and friendly metal 750. Here, the coil 710 may operate on the basis of MPP, and the magnet 720 may be formed to at least partially surround the coil 710. The thickness of the friendly metal 750 may be 0.7 mm. As the thickness of the friendly metal is smaller, open-air R is larger and open-air Q is smaller. The receiver as shown in FIGS. 7A and 7B may have thinner friendly metal compared to the receiver as shown in FIGS. 6A and 6B. Except for the thickness of the friendly metal, the components of the receiver as shown in FIGS. 7A and 7B may be identical to those of the receiver as shown in FIGS. 6A and 6B.

According to one embodiment of the invention, in first and second embodiments to be described later, one pair of the transmitters and receivers shown in FIGS. 4 to 7 may be selected to perform simulations, depending on the conditions related to the transmitter/receiver pair. The conditions related to the transmitter/receiver pair required for performing simulations in each embodiment will be described later.

Meanwhile, according to one embodiment of the invention, the transmitter and receiver may each include a configuration (not shown) for computational processing. This configuration may be referred to as a control circuit, and may consist of components such as a processor and memory. Further, this configuration may be formed as functional modules. For example, the configuration for computational processing may be formed as modules referred to as an acquisition unit, an estimation management unit, and the like in each of the transmitter and receiver. These functional modules may be understood as included in the aforementioned control circuit. The improved MPLA method will be described with the functional modules as the main entities.

According to one embodiment of the invention, when the transmitter performs the improved MPLA method, the acquisition unit may acquire information on at least one of the distance between the transmitter and receiver (z-distance) and the rectified voltage of the receiver V_{RECT}, and the estimation management unit may estimate power loss due to friendly metal P_{FM} with reference to the acquired information.

Further, according to one embodiment of the invention, when the receiver performs the improved MPLA method, the acquisition unit may acquire information on at least one of the distance between the transmitter and receiver (z-distance) and the rectified voltage of the receiver V_{RECT}, and the estimation management unit may cause power loss due to friendly metal P_{FM} to be estimated with reference to the acquired information.

According to one embodiment of the invention, the improved MPLA method described as being performed by the functional modules may also be described as being performed by the transmitter or receiver itself as the main entity, or by the control circuit included in the transmitter or receiver as the main entity.

Hereinafter, an embodiment where the improved MPLA method is implemented dependently on the z-distance (hereinafter, “first embodiment”) and an embodiment where the improved MPLA method is implemented dependently on the z-distance and V_{RECT} (hereinafter, “second embodiment”) will be described. Meanwhile, an embodiment where the improved MPLA method is implemented dependently on V_{RECT} (hereinafter, “third embodiment”) may be easily derived from the first and second embodiments, and thus a detailed description thereof will be omitted. Of course, the third embodiment should also be understood as included in the improved MPLA method proposed in the invention. Meanwhile, although the embodiments described below are described with the transmitter or receiver as the main entity, it should be noted that the embodiments may also be described with the aforementioned control circuit or functional modules as the main entities.

### First Embodiment: Improved MPLA Method Dependent on z-Distance

In this embodiment, under the condition where V_{RECT} is fixed at 14V and the transmitter/receiver pair correspond to TG, simulations of the conventional MPLA method and the improved MPLA method are performed to compare and evaluate their performance, and then it is described how to implement the improved MPLA method in the transmitter and receiver.

Meanwhile, the simulations are also performed under the condition where load power, which is defined as the product of V_{RECT} and I_{RECT}, is 10 W, 12.5 W, and 15 W, in addition to the above condition. Further, the simulations are performed under the condition where the transmitter is located at (0, 0, 0) and the receiver is located at (0, 0, 0), (0, 0, 2), (2, 0, 0), and (2, 0, 2) in a three-dimensional orthogonal coordinate system. Here, when the y-coordinate is omitted from the receiver's coordinates, the simulations may also be represented as performed at (0, 0), (0, 2), (2, 0), and (2, 2).

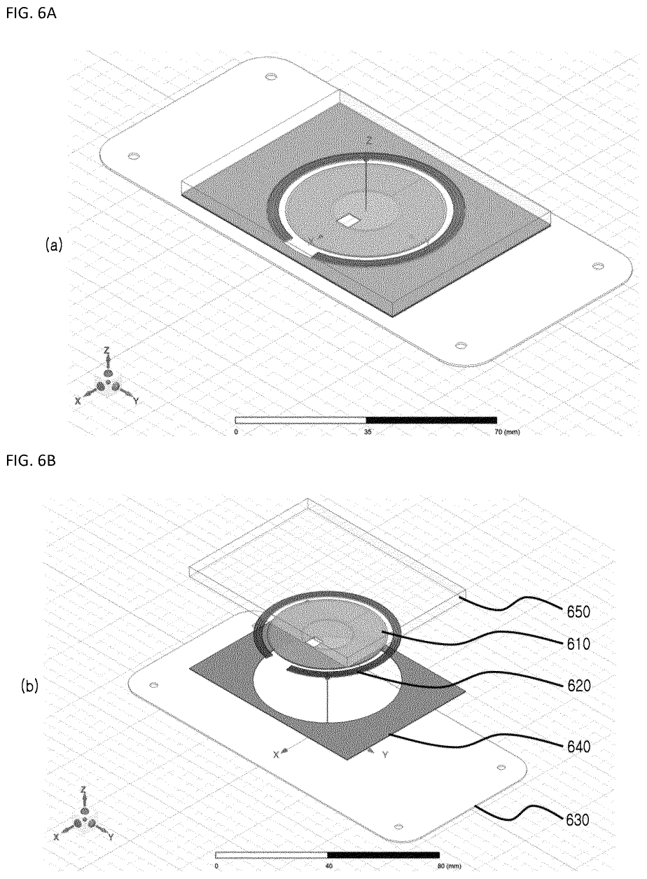

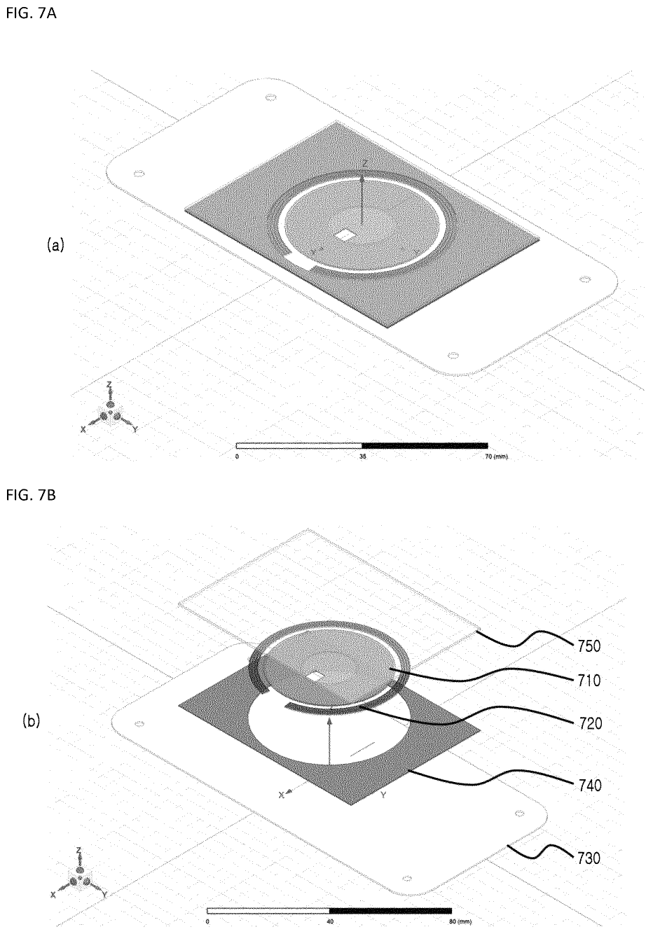

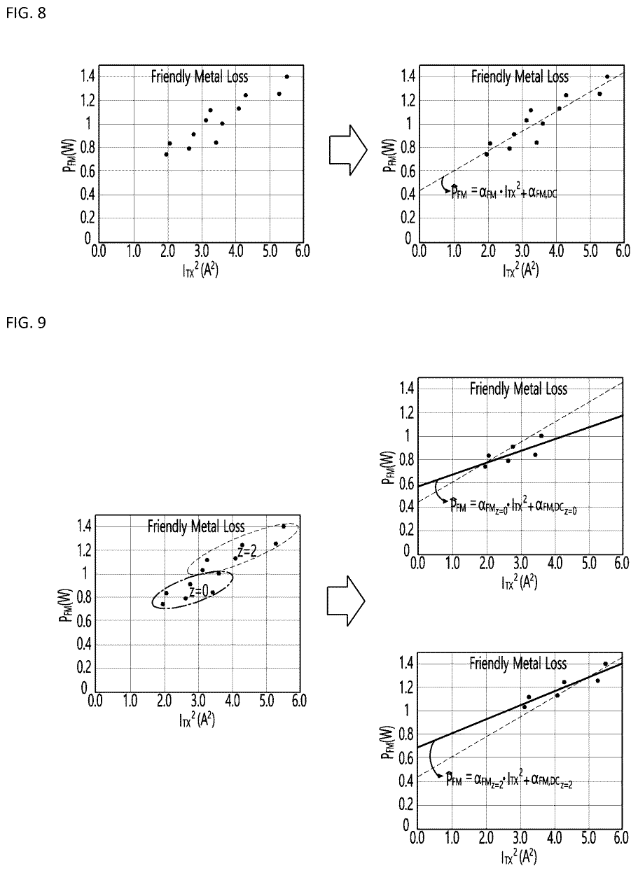

According to one embodiment of the invention, the conventional MPLA method derives a linear model for P_{FM} without considering the z-distance as shown in FIG. 8, whereas the improved MPLA method may derive multiple linear models for P_{FM} depending on the z-distance as shown in FIG. 9. Two linear models are shown in FIG. 9 since the z-distance is basically configured as 0 mm or 2 mm, and they are integrated and shown in a single graph in FIG. 10.

According to one embodiment of the invention, the improved MPLA method may represent α_{FM} and α_{FM,DC}, among the MPLA coefficients, as α_{FMZ=0} and α_{FM, DCz=0}, Or α_{FMz=2} and α_{FM, DCz=2}, depending on the z-distance. In FIG. 10, the MPLA coefficients α_{FM} and α_{FM, DC} in the conventional MPLA method are calculated as α_{FM}=0.1682 and α_{FM,DC}=0.4632, respectively. Further, the MPLA coefficients α_{FMz=0} and α_{FM, DCz=0} in the improved MPLA method are calculated as α_{FMz=0}=0.0996 and α_{FM, DCz=0}=0.5803, respectively, and α_{FMz=2} and α_{FM, DCz=2} are calculated as α_{FMz=2}=0.1198 and α_{FM, DCz=2}=0.6848, respectively.

According to one embodiment of the invention, regarding P_{FM} in the improved MPLA method, a relationship equation P_{FMz=0}=g_{FMz=0}α_{FMz=0} I_{Tx}²+g_{FM,DCz=0}α_{FM,DCz=0} may be derived when the z-distance is 0 mm, and a relationship equation P_{FMz=2}=g_{FMz=2}α_{FMz=2}I_{Tx}²+g_{FM, DCz=2}α_{FM, DCz=2} may be derived when the z-distance is 2 mm. These are integrated to derive a relationship equation for estimating P_{FM} in the improved MPLA method dependent on the z-distance as P_{FMz=i}=g_{FMz=i}αF_{Mz=i}I_{Tx}²+g_{FM,DCz=i}α_{FM,DCz=i}.

According to one embodiment of the invention, root mean square errors (RMSEs) of the conventional MPLA method and the improved MPLA method are shown in Table 1. The unit is mW.

TABLE 1

| z-distance | | |
|---|---|---|
| (mm) | Conventional MPLA method | Improved MPLA method |
| 0 | 82 | 55 |
| 2 | 77 | 47 |
| All | 80 | 51 |

According to one embodiment of the invention, compared to the conventional MPLA method, the improved MPLA method demonstrates RMSE performance advantages of about 32.6% when the z-distance is 0 mm, about 39.4% when the z-distance is 2 mm, and about 35.7% on the whole.

According to one embodiment of the invention, two approaches may be considered for implementing the improved MPLA method dependent on the z-distance in the transmitter and receiver.

First, the first approach will be described.

The transmitter may store E_{0xg} and E_{1xg}, and the receiver may store V_{RECT}, β₀ᵣₓ, α₁ᵣₓ, and αₖₜₕ. The receiver may transmit V_{RECT}, α₀ᵣₓ, α₁ᵣₓ, and αₖₜₕ to the transmitter using an XID packet. The transmitter may estimate a coupling coefficient kₑₛₜ using the stored E_{0xg}, E_{1xg}, V_{RECT}, α₀ᵣₓ, α₁ᵣₓ, and αₖₜₕ along with the measured Vᵢₙᵥ and V_{CTX_PP}. A relationship equation for estimating kₑₛₜ is

$${k}_{est} = {E}_{0 xg} \cdot {α}_{0 rx} \cdot p + {E}_{1 xg} \cdot {α}_{1 rx} = {E}_{0 xg} \cdot {α}_{0 rx} \cdot \frac{{V}_{RECT}}{{V}_{inv} + {V}_{CTX \_ PP}} + {E}_{1 xg} \cdot {α}_{1 rx} .$$

Meanwhile, E_{{a} {b} {c}} may be referred to as an eigen coefficient. Here, {a} may be 0 or 1, where 0 may represent the slope of the linear model, and 1 may represent the y-intercept of the linear model. Also, {b} may be g or x, where g may refer to the reference transmitter (Ref. PTx (TPT)) defined by the Qi standard, and x may refer to a general (or unknown) transmitter (General PTx). Further, {c} may be g or y, where g may refer to the reference receiver (Ref. PRx (TPR)) defined by the Qi standard, and y may refer to a general (or unknown) receiver (General PRx).

Further, the transmitter may transmit kₑₛₜ to the receiver using a KEST packet. Here, the transmitter and receiver may each determine a current coupling condition by comparing kₑₛₜ with a reference value. Here, the reference value may be 0.81×αₖₜₕ.

Further, the transmitter may store scaling factors dependent on the z-distance, and the receiver may store MPLA coefficients dependent on the z-distance. Specifically, the transmitter may store g_{coil,Rx}, g_{FMz=0}, g_{FM,DCz=0}, g_{FMz=2}, and g_{FM,DCz=2} corresponding to the scaling factors, and the receiver may store g_{coil,Tx} corresponding to the scaling factors and α_{FMz=0}, α_{FM,DCz=0}, α_{FMz=2}, and α_{FM, DCz=2} corresponding to the MPLA coefficients. Here, g_{FMz=i} and g_{FM, DCz=i} are defined as

$$\text{?} = \frac{\text{?}}{\text{?}} \approx \frac{\text{?}}{\text{?}} and \text{?} = \frac{\text{?}}{\text{?}} \approx \frac{\text{?}}{\text{?}} ,$$

$$\text{?} \text{indicates text missing or illegible when filed}$$

respectively. In other words, the transmitter may store the scaling factors g_{FMz=i} and g_{FM, DCz=i} dependent on the z-distance, and the receiver may store the MPLA coefficients α_{FMz=i}, and α_{FM,DCz=i} dependent on the z-distance.

Further, if the determined coupling condition corresponds to a first level (or a high level) (i.e., kₑₛₜ is greater than or equal to 0.81×αₖₜₕ), the transmitter selects g_{FMz=0} and g_{FM, DCz=0} among the stored scaling factors as scaling factors for estimating P_{FM}, and g_{coil,Rx} may be transmitted to the receiver using a PLA packet. Additionally, the receiver may transmit g_{coil,Tx} corresponding to the stored scaling factors and α_{FMz=0} and α_{FM, DCz=0} among the stored MPLA coefficients to the transmitter using a PLA packet. According to the scaling factors selected by the transmitter or the MPLA coefficients transmitted by the receiver, the z-distance may be determined on the basis of kₑₛₜ, specifically as 0 mm in response to kₑₛₜ being greater than or equal to 0.81×βₖₜₕ.

Alternatively, if the determined coupling condition corresponds to a second level (or a low level) (i.e., kₑₛₜ is less than 0.81×αₖₜₕ), the transmitter selects g_{FMz=2} and g_{FM, DCz=2} among the stored scaling factors as scaling factors for estimating P_{FM}, and g_{coil,Rx} may be transmitted to the receiver using a PLA packet. Additionally, the receiver may transmit g_{coil,Tx} corresponding to the stored scaling factors and α_{FMz=2} and α_{FM, DCz=2} among the stored MPLA coefficients to the transmitter using a PLA packet. According to the scaling factors selected by the transmitter or the MPLA coefficients transmitted by the receiver, the z-distance may be determined on the basis of kₑₛₜ, specifically as 2 mm in response to kₑₛₜ being less than 0.81×αₖₜₕ.

Further, the transmitter may estimate P_{FM} with reference to the selected scaling factors and the received MPLA coefficients (i.e., information acquired regarding the z-distance). This may also be described as the receiver causing P_{FM} to be estimated by the transmitter. Here, P_{FM} may be estimated from a relationship equation P_{FM}=_{gFMz=i} α_{FMz=i} I_{Tx}²+g_{FM,DCz=i} α_{FM,DCz=i}. Meanwhile, the transmitter may estimate P_{coil loss,Tx} in addition to P_{FM}, and the receiver may estimate P_{coil loss, Rx}.

Next, the second approach will be described.

The transmitter may store E_{0xg} and E_{1xg}, and the receiver may store V_{RECT}, α₀ᵣₓ, α₁ᵣₓ, and αₖₜₕ. The receiver may transmit V_{RECT}, α₀ᵣₓ, α₁ᵣₓ, and αₖₜₕ to the transmitter using an XID packet. The transmitter may estimate a coupling coefficient kₑₛₜ using the stored E_{0xg}, E_{1xg}, V_{RECT}, α₀ᵣₓ, α₁ᵣₓ, and αₖₜₕ along with the measured Vᵢₙᵥ and V_{CTX_PP}. A relationship equation for estimating kₑₛₜ is

$${k}_{est} = {E}_{0 xg} \cdot {α}_{0 rx} \cdot p + {E}_{1 xg} \cdot {α}_{1 rx} = {E}_{0 xg} \cdot {α}_{0 rx} \cdot \frac{{V}_{RECT}}{\text{?}} + {E}_{1 xg} \cdot {α}_{1 rx} .$$

$$\text{?} \text{indicates text missing or illegible when filed}$$

Meanwhile, E_{{a} {b} {c}} may be referred to as an eigen coefficient. Here, {a} may be 0 or 1, where 0 may represent the slope of the linear model, and 1 may represent the y-intercept of the linear model. Also, {b} may be g or x, where g may refer to the reference transmitter (Ref. PTx (TPT)) defined by the Qi standard, and x may refer to a general (or unknown) transmitter (General PTx). Further, {c} may be g or y, where g may refer to the reference receiver (Ref. PRx (TPR)) defined by the Qi standard, and y may refer to a general (or unknown) receiver (General PRx).

Further, the transmitter and receiver may each determine a current coupling condition by comparing kₑₛₜ with a reference value. Here, the reference value may be 0.81×αₖₜₕ. The transmitter may transmit kₑₛₜ along with information corresponding to kₑₛₜ to the receiver using a KEST packet (in some cases, the KEST packet transmitted from the transmitter to the receiver may be referred to as a first packet). Specifically, if the determined coupling condition corresponds to a first level (or a high level) (i.e., kₑₛₜ is greater than or equal to 0.81×αₖₜₕ), the transmitter may assign 0 to reserved bits of the KEST packet as the information corresponding to kₑₛₜ. Further, if the determined coupling condition corresponds to a second level (or a low level) (i.e., kₑₛₜ is less than 0.81×αₖₜₕ), the transmitter may assign 1 to the reserved bits of the KEST packet as the information corresponding to kₑₛₜ. Meanwhile, the KEST packet may consist of three bytes, where bits b7 to b4 of a second byte B1 may correspond to the reserved bits.

Further, the transmitter may store scaling factors dependent on the z-distance, and the receiver may store MPLA coefficients dependent on the z-distance. Specifically, the transmitter may store g_{coil,Rx}, g_{FMz=0}, g_{FM, DCz=0}, g_{FMz=2}, and g_{FM, DCz=2} corresponding to the scaling factors, and the receiver may store g_{coil,Tx} corresponding to the scaling factors and α_{FMz=0}, α_{FM, DCz=0}, α_{FMz=2}, and α_{FM,DCz=2} corresponding to the MPLA coefficients. Here, g_{FMz=i} and g_{FM,DCz=i} are defined as

$$\text{?} = \frac{\text{?}}{\text{?}} \approx \frac{\text{?}}{\text{?}} and \text{?} = \frac{\text{?}}{\text{?}} \approx \frac{\text{?}}{\text{?}} ,$$

$$\text{?} \text{indicates text missing or illegible when filed}$$

respectively. In other words, the transmitter may store the scaling factors g_{FMz=i} and g_{FM, DCz=i} dependent on the z-distance, and the receiver may store the MPLA coefficients α_{FMz=i}, and α_{FM,DC2=i} dependent on the z-distance.

Further, if the information assigned to the reserved bits is 0 (i.e., the determined coupling condition corresponds to the first level (or high level), or kₑₛₜ is greater than or equal to 0.81×αₖₜₕ), the transmitter selects g_{FMz=0} and g_{FM, DCz=0} among the stored scaling factors as scaling factors for estimating P_{FM}, and g_{coil,Rx} may be transmitted to the receiver using a PLA packet. Additionally, the receiver may transmit g_{coil,Tx} corresponding to the stored scaling factors and α_{FMz=0} and d_{FM, DCz=0} among the stored MPLA coefficients to the transmitter using a PLA packet. According to the scaling factors selected by the transmitter or the MPLA coefficients transmitted by the receiver, the z-distance may be determined on the basis of kₑₛₜ, specifically as 0 mm in response to kₑₛₜ being greater than or equal to 0.81×αₖₜₕ.

Alternatively, if the information assigned to the reserved bits is 1 (i.e., the determined coupling condition corresponds to the second level (or low level), or kₑₛₜ is less than 0.81×αₖₜₕ), the transmitter selects g_{FMz=2} and g_{FM, DCz=2} among the stored scaling factors as scaling factors for estimating P_{FM}, and g_{coil,Rx} may be transmitted to the receiver using a PLA packet. Additionally, the receiver may transmit g_{coil,Tx} corresponding to the stored scaling factors and α_{FMz=2} and α_{FM, DCz=2} among the stored MPLA coefficients to the transmitter using a PLA packet. According to the scaling factors selected by the transmitter or the MPLA coefficients transmitted by the receiver, the z-distance may be determined on the basis of kₑₛₜ, specifically as 2 mm in response to kₑₛₜ being less than 0.81×αₖₜₕ.

Further, the transmitter may estimate P_{FM} with reference to the selected scaling factors and the received MPLA coefficients (i.e., information acquired regarding the z-distance). This may also be described as the receiver causing P_{FM} to be estimated by the transmitter. Here, P_{FM} may be estimated from a relationship equation P_{FM}=g_{FMz=i} α_{FMz=i} I_{Tx}²+g_{FM,DCz=i} α_{FM,DCz=i}. Meanwhile, the transmitter may estimate P_{coil loss,Tx} in addition to P_{FM}, and the receiver may estimate P_{coil loss, Rx}.

### Second Embodiment: Improved MPLA Method Dependent on z-Distance and V_{RECT}

In this embodiment, under the condition where the transmitter/receiver pair correspond to TR, simulations of the conventional MPLA method and the improved MPLA method are performed to compare and evaluate their performance, and then it is described how to implement the improved MPLA method in the transmitter and receiver.

Meanwhile, the simulations are also performed under the condition where load power, which is defined as the product of V_{RECT} and I_{RECT}, is 2.5 W, 5 W, 7.5 W, 10 W, 12.5 W, and 15 W, in addition to the above condition. Here, 2.5 W, 5 W, and 7.5 W correspond to the case where V_{RECT} is 12V, and 10 W, 12.5 W, and 15 W correspond to the case where V_{RECT} is 14V. Further, the simulations are performed under the condition where the transmitter is located at (0, 0, 0) and the receiver is located at (0, 0, 0), (0, 0, 2), (2, 0, 0), and (2, 0, 2) in a three-dimensional orthogonal coordinate system. Here, when the y-coordinate is omitted from the receiver's coordinates, the simulations may also be represented as performed at (0, 0), (0, 2), (2, 0), and (2, 2).

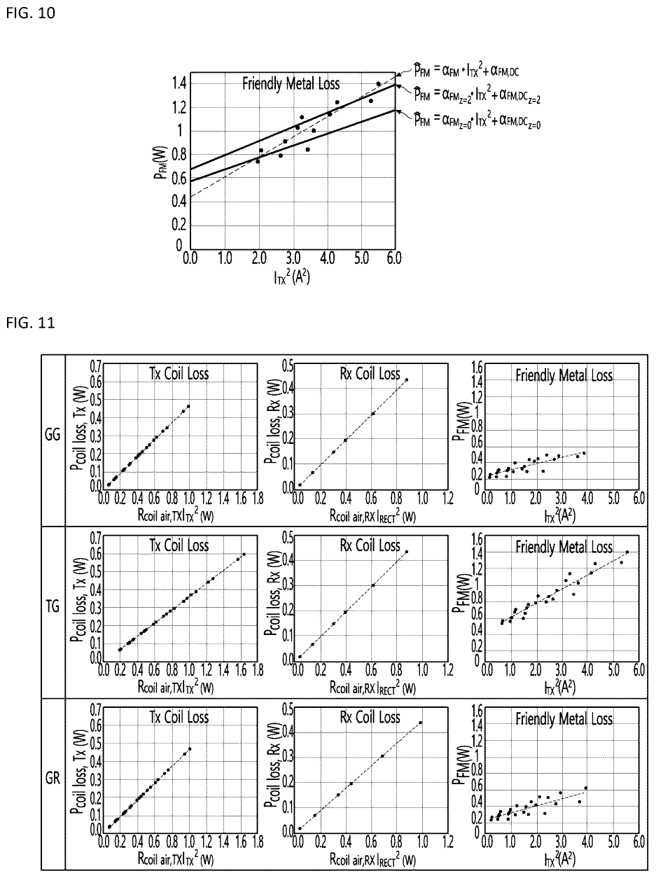

As shown in FIG. 11, the conventional MPLA method derives linear models for P_{FM} without considering the z-distance and V_{RECT} under GG, TG, and GR conditions. The MPLA coefficients under each condition are shown in Table 2.

TABLE 2

| | b_{coil} | m_{coil} | α_{FM} | α_{FM, DC} |
|---|---|---|---|---|
| GG | 0.4649 | 0.4939 | 0.0796 | 0.1667 |
| TG | 0.3661 | 0.4939 | 0.1805 | 0.3861 |
| GR | 0.4650 | 0.4385 | 0.0911 | 0.1701 |

Further, the scaling factors under each condition are shown in Table 3.

TABLE 3

| g_{coil, Tx} | g_{coil, Rx} | g_{FM} | g_{FM, DC} |
|---|---|---|---|
| 1.000 | 1.000 | 2.2676 | 2.3161 |

In the conventional MPLA method under the TR condition, the estimated value of P_{coil loss,Tx} is calculated as

$${\hat{P}}_{coil loss , Tx} = {b}_{coil}^{TR} {R}_{coil air , Tx} {I}_{Tx}^{2} \approx {g}_{coil , Tx} {b}_{coil}^{TG} {R}_{coil air , Tx} {I}_{Tx}^{2} = {b}_{coil}^{TG} {R}_{coil air , Tx} {I}_{Tx}^{2} = 0.3661 {R}_{coil air , Tx} {I}_{Tx}^{2} ,$$

and the estimated value of P_{coil loss, Rx} is calculated as

$${\hat{P}}_{coil loss , Rx} = {m}_{coil}^{TR} {R}_{coil air , Rx} {I}_{RECT}^{2} \approx {g}_{coil , Rx} {m}_{coil}^{GR} {R}_{coil air , Rx} {I}_{RECT}^{2} = {m}_{coil}^{GR} {R}_{coil air , Rx} {I}_{RECT}^{2} = 0.4385 {R}_{coil air , Rx} {I}_{RECT}^{2} .$$

Additionally, in the conventional MPLA method under the TR condition, the estimated value of P_{FM} is calculated as

$${\hat{P}}_{FM} = {α}_{FM}^{TR} {I}_{Tx}^{2} + {α}_{FM , DC}^{TR} \approx {g}_{FM} {α}_{FM}^{GR} {I}_{Tx}^{2} + {g}_{FM , DC} {α}_{FM , DC}^{GR} = 2.2676 \times 0.0911 {I}_{Tx}^{2} + 2.3161 \times 0.1701 = 0.2066 {I}_{Tx}^{2} + 0.394 .$$

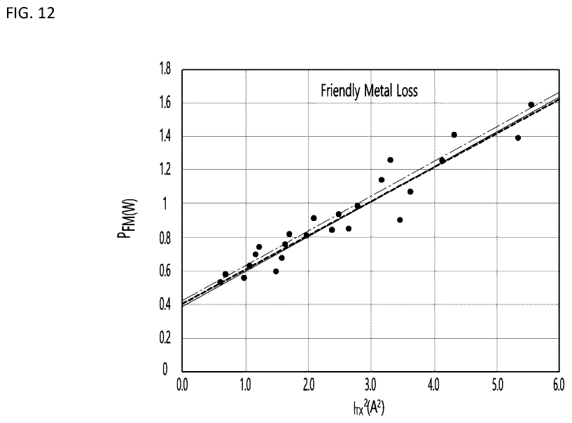

FIG. 12 shows linear models for P_{FM} derived by the conventional MPLA method under the TR condition. The model shown with a dotted line (hereinafter, model (a)) is a linear model for P_{FM} derived without applying the scaling factors, in which case the estimated value of PEM is \hat{P}_{FM}=0.2010I_{Tx}²+0.4151. The model shown with a dash-dotted line (hereinafter, model (b)) is derived by applying the scaling factors under the condition where V_{RECT} is 14V. In this case, the estimated value of P_{FM} is \hat{P}_{FM}=0.2086I_{Tx}²+0.4184 Further, the model shown with a solid line (hereinafter, model (c)) is derived by applying the scaling factors under the condition where V_{RECT} is between 12V and 14V. In this case, the estimated value of P_{FM} is \hat{P}_{FM}=0.2066I_{Tx}²+0.3940.

According to one embodiment of the invention, RMSEs of the three models shown in FIG. 12 are shown in Table 4. The unit is mW.

TABLE 4

| | Model (a) | Model (b) | Model (c) |
|---|---|---|---|
| RMSE | 83.8 | 87.3 | 84.5 |

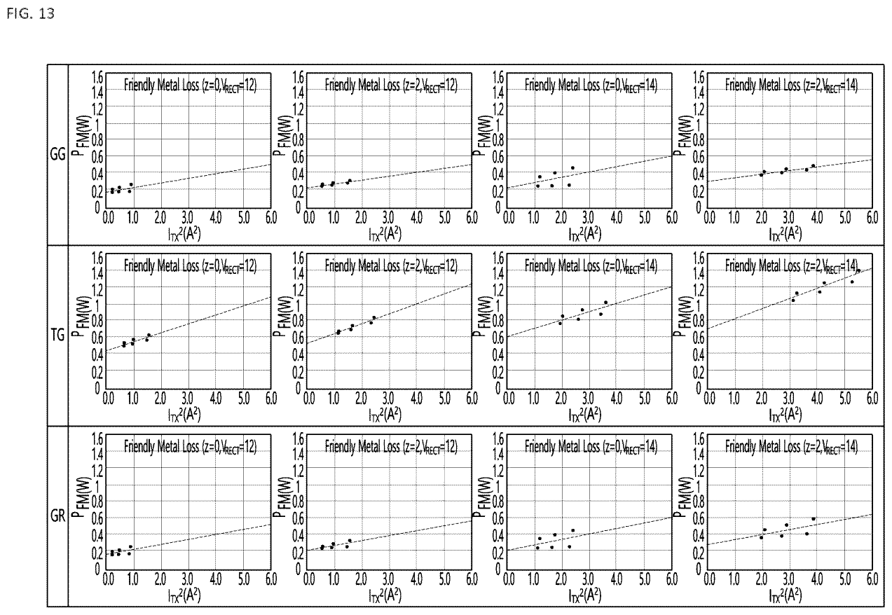

According to one embodiment of the invention, the conventional MPLA method derives a linear model for P_{FM} without considering the z-distance and V_{RECT}, whereas the improved MPLA method may derive multiple linear models for P_{FM} depending on the z-distance and V_{RECT} as shown in FIG. 13. Basically, since the z-distance is configured as 0 mm or 2 mm and V_{RECT} is configured as 12V or 14V, four linear models for each condition related to the transmitter/receiver pair are shown in FIG. 13. FIG. 13 shows the GG, TG, and GR conditions.

According to one embodiment of the invention, the MPLA coefficients under the condition where V_{RECT} is 12V are shown in Table 5.

TABLE 5

| V_{RECT} = | z = 0 mm | | z = 2 mm | |
|---|---|---|---|---|
| 12 V | α_{FM}¹²_{z=0} | α_{FM, DC}¹²_{z=0} | α_{FM}¹²_{z=2} | α_{FM, DC}¹²_{z=2} |
| GG | 0.0570 | 0.1588 | 0.0425 | 0.2125 |
| TG | 0.1015 | 0.4335 | 0.1213 | 0.5056 |
| GR | 0.0588 | 0.1674 | 0.0544 | 0.2208 |

Further, according to one embodiment of the invention, the MPLA coefficients under the condition where V_{RECT} is 14V are shown in Table 6.

TABLE 6

| V_{RECT} = | z = 0 mm | | z = 2 mm | |
|---|---|---|---|---|
| 14 V | α_{FM}¹⁴_{z=0} | α_{FM, DC}¹⁴_{z=0} | α_{FM}¹⁴_{z=2} | α_{FM, DC}¹⁴_{z=2} |
| GG | 0.0639 | 0.1945 | 0.0410 | 0.2882 |
| TG | 0.1009 | 0.5812 | 0.1198 | 0.6850 |
| GR | 0.0647 | 0.2082 | 0.0582 | 0.2792 |

Further, according to one embodiment of the invention, the scaling factors under the condition where V_{RECT} is 12V are shown in Table 7.

TABLE 7

| | |
|---|---|
| z = 0 mm | z = 2 mm |

| g_{FM}¹²_{z=0} | g_{FM, DC}¹²_{z=0} | g_{FM}¹²_{z=2} | g_{FM, DC}¹²_{z=2} |
|---|---|---|---|
| 1.7807 | 2.7298 | 2.8541 | 2.3793 |

Further, according to one embodiment of the invention, the scaling factors under the condition where V_{RECT} is 14V are shown in Table 8.

TABLE 8

| | |
|---|---|
| z = 0 mm | z = 2 mm |

| g_{FM}¹⁴_{z=0} | g_{FM, DC}¹⁴_{z=0} | g_{FM}¹⁴_{z=2} | g_{FM, DC}¹⁴_{z=2} |
|---|---|---|---|
| 1.5790 | 2.9882 | 2.9220 | 2.3768 |

According to one embodiment of the invention, the improved MPLA method may estimate P_{FM} under the TR condition depending on the z-distance and V_{RECT}.

Specifically, when the z-distance is 0 mm and V_{RECT} is 12V, the estimated value of P_{FM} is calculated as

$${\hat{P}}_{{FM}_{z = 0}^{12}} = {α}_{{FM}_{z = 0}^{12}}^{TR} {I}_{Tx}^{2} + {α}_{FM , {DC}_{z = 0}^{12}}^{TR} \approx {g}_{{FM}_{z = 0}^{12}} {α}_{{FM}_{z = 0}^{12}}^{GR} {I}_{Tx}^{2} + {g}_{FM , {DC}_{z = 0}^{12}} {α}_{FM , {DC}_{z = 0}^{12}}^{GR} = 1.7807 \times 0.0588 {I}_{Tx}^{2} + 2.7298 \times 0.1674 = 0.1047 {I}_{Tx}^{2} + 0.457 .$$

Further, when the z-distance is 2 mm and V_{RECT} is 12V, the estimated value of P_{FM} is calculated as

$${\hat{P}}_{{FM}_{z = 2}^{12}} = {α}_{{FM}_{z = 2}^{12}}^{TR} {I}_{Tx}^{2} + {α}_{FM , {DC}_{z = 2}^{12}}^{TR} \approx {g}_{{FM}_{z = 2}^{12}} {α}_{{FM}_{z = 2}^{12}}^{GR} {I}_{Tx}^{2} + {g}_{FM , {DC}_{z = 2}^{12}} {α}_{FM , {DC}_{z = 2}^{12}}^{GR} = 2.8541 \times 0.0544 {I}_{Tx}^{2} + 2.3793 \times 0.2208 = 0.1553 {I}_{Tx}^{2} + 0.5253 .$$

Further, when the z-distance is 0 mm and V_{RECT} is 14V, the estimated value of P_{FM} is calculated as

$${\hat{P}}_{{FM}_{z = 0}^{14}} = {α}_{{FM}_{z = 0}^{14}}^{TR} {I}_{Tx}^{2} + {α}_{FM , {DC}_{z = 0}^{14}}^{TR} \approx {g}_{{FM}_{z = 0}^{14}} {α}_{{FM}_{z = 0}^{14}}^{GR} {I}_{Tx}^{2} + {g}_{FM , {DC}_{z = 0}^{14}} {α}_{FM , {DC}_{z = 0}^{14}}^{GR} = 1.579 \times 0.0647 {I}_{Tx}^{2} + 2.9882 \times 0.2082 = 0.1022 {I}_{Tx}^{2} + 0.6221 .$$

Further, when the z-distance is 2 mm and V_{RECT} is 14V, the estimated value of P_{FM} is calculated as

$${\hat{P}}_{{FM}_{z = 2}^{14}} = {α}_{{FM}_{z = 2}^{14}}^{TR} {I}_{Tx}^{2} + {α}_{FM , {DC}_{z = 2}^{14}}^{TR} \approx {g}_{{FM}_{z = 2}^{14}} {α}_{{FM}_{z = 2}^{14}}^{GR} {I}_{Tx}^{2} + {g}_{FM , {DC}_{z = 2}^{14}} {α}_{FM , {DC}_{z = 2}^{14}}^{GR} = 2.922 \times 0.0582 {I}_{Tx}^{2} + 2.3768 \times 0.2792 = 0.1701 {I}_{Tx}^{2} + 0.6636 .$$

Here, the scaling factors

$$\text{?} and \text{?}$$

$$\text{?} \text{indicates text missing or illegible when filed}$$

are defined as

$$\text{?} = \frac{\text{?}}{\text{?}} \approx \frac{\text{?}}{\text{?}} and \text{?} = \frac{\text{?}}{\text{?}} \approx \frac{\text{?}}{\text{?}} ,$$

$$\text{?} \text{indicates text missing or illegible when filed}$$

respectively.

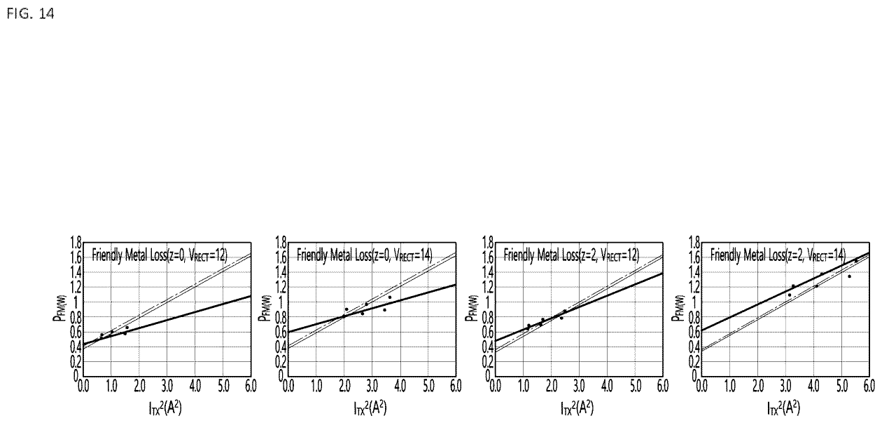

FIG. 14 shows linear models for P_{FM} derived by the improved MPLA method under the TR condition. However, the models shown with a dash-dotted line and a solid line in FIG. 14 correspond to models (b) and (c) of the conventional MPLA method, respectively. The model shown with a bold solid line in FIG. 14 is a linear model for P_{FM} derived by the improved MPLA method, and its relationship equation is

$$\text{?} = \text{?} {I}_{tx}^{2} + \text{?} .$$

$$\text{?} \text{indicates text missing or illegible when filed}$$

According to one embodiment of the invention, RMSEs of the three models shown in FIG. 14 are shown in Table 9. The unit is mW.

TABLE 9

| | Model (b) of the | Model (c) of the | Model of the |
|---|---|---|---|
| | conventional | conventional | improved |
| | MPLA method | MPLA method | MPLA method |
| RMSE | 87.3 | 84.5 | 60.9 |

According to one embodiment of the invention, the model of the improved MPLA method demonstrates RMSE performance advantages of about 30.2% compared to model (b) of the conventional MPLA method, and about 27.9% compared to model (c) of the conventional MPLA method.

According to one embodiment of the invention, it will be described below how to implement the improved MPLA method dependent on the z-distance and V_{RECT} in the transmitter and receiver.

The transmitter may store E_{0xg} and E_{1xg}, and the receiver may store V_{RECT}, α0ᵣₓ, α₁ᵣₓ, and αₖₜₕ. The receiver may transmit V_{RECT}, α₀ᵣₓ, α₁ᵣₓ, and auth to the transmitter using an XID packet. The transmitter may estimate a coupling coefficient kₑₛₜ using the stored E_{0xg}, E_{1xg}, V_{RECT}, α₀ᵣₓ, α₁ᵣₓ, and αₖₜₕ along with the measured Viny and VCTx_PP. A relationship equation for estimating kₑₛₜ is

$${k}_{est} = {E}_{0 xg} \text{?} {α}_{0 rx} \cdot p + {E}_{1 xg} \cdot {α}_{1 rx} = {E}_{0 xg} \cdot {α}_{0 rx} \cdot \frac{{V}_{RECT}}{\text{?}} + {E}_{1 xg} \cdot {α}_{1 rx} .$$

$$\text{?} \text{indicates text missing or illegible when filed}$$

Meanwhile, E_{{a} {b} {c}} may be referred to as an eigen coefficient. Here, {a} may be 0 or 1, where 0 may represent the slope of the linear model, and 1 may represent the y-intercept of the linear model. Also, {b} may be g or x, where g may refer to the reference transmitter (Ref. PTx (TPT)) defined by the Qi standard, and x may refer to a general (or unknown) transmitter (General PTx). Further, {c} may be g or y, where g may refer to the reference receiver (Ref. PRx (TPR)) defined by the Qi standard, and y may refer to a general (or unknown) receiver (General PRx).

Further, the transmitter may transmit kₑₛₜ to the receiver using a KEST packet. Here, the transmitter and receiver may each determine a current coupling condition by comparing kₑₛₜ with a reference value. Here, the reference value may be 0.81×Økth.

Further, the transmitter may store scaling factors dependent on the z-distance and V_{RECT}, and the receiver may store MPLA coefficients dependent on the z-distance and V_{RECT}-Specifically, the transmitter may store

$${g}_{coil , Rx} , ( {g}_{{FM}_{z = 0}^{12}} , {g}_{FM , {DC}_{z = 0}^{12}} ) , ( {g}_{{FM}_{z = 0}^{14}} , {g}_{FM , {DC}_{z = 0}^{14}} ) ,$$

$$( {g}_{{FM}_{z = 0}^{Vmax}} , {g}_{FM , {DC}_{z = 0}^{Vmax}} ) , ( {g}_{{FM}_{z = 2}^{12}} , {g}_{FM , {DC}_{z = 2}^{12}} ) ,$$

$$( {g}_{{FM}_{z = 2}^{14}} , {g}_{FM , {DC}_{z = 2}^{14}} ) , and ( {g}_{{FM}_{z = 2}^{Vmax}} , {g}_{FM , {DC}_{z = 2}^{Vmax}} )$$

corresponding to the scaling factors, and the receiver may store g_{coil,Tx} corresponding to the scaling factors and

$$( {α}_{{FM}_{z = 0}^{12}}^{GR} , {α}_{FM , {DC}_{z = 0}^{12}}^{GR} ) , ( {α}_{{FM}_{z = 0}^{14}}^{GR} , {α}_{FM , {DC}_{z = 0}^{14}}^{GR} ) , ( {α}_{{FM}_{z = 0}^{Vmax}}^{GR} , {α}_{FM , {DC}_{z = 0}^{Vmax}}^{GR} ) ,$$

$$( {α}_{{FM}_{z = 2}^{12}}^{GR} , {α}_{FM , {DC}_{z = 2}^{12}}^{GR} ) , ( {α}_{{FM}_{z = 2}^{14}}^{GR} , {α}_{FM , {DC}_{z = 2}^{14}}^{GR} ) , and ( {α}_{{FM}_{z = 2}^{Vmax}}^{GR} , {α}_{FM , {DC}_{z = 2}^{Vmax}}^{GR} )$$

corresponding to the MPLA coefficients. Here, what is enclosed in parentheses may be understood as a single set. In other words, the transmitter may store the scaling factors

$$\{ \text{?} , \text{?} \}$$

$$\text{?} \text{indicates text missing or illegible when filed}$$

dependent on the z-distance and V_{RECT}, and the receiver may store the MPLA coefficients

$$\{ \text{?} , \text{?} \}$$

$$\text{?} \text{indicates text missing or illegible when filed}$$

dependent on the z-distance and V_{RECT}.

Further, the transmitter may transmit g_{coil,Rx} among the stored scaling factors to the receiver using a PLAP packet. Further, the receiver may transmit g_{coil,Tx} corresponding to the stored scaling factors and all the stored MPLA coefficients to the transmitter using a PLAP packet (in some cases, the PLAP packet transmitted from the receiver to the transmitter may be referred to as a second packet). Here, when transmitting the MPLA coefficients to the transmitter, the receiver may transmit different PLAP packets for respective MPLA coefficients (or respective sets of MPLA coefficients). Specifically, the PLAP packet may consist of 7 bytes, where a second byte B1 and a third byte B2 may be assigned information corresponding to

$$\text{?} ,$$

$$\text{?} \text{indicates text missing or illegible when filed}$$

a fourth byte B3 and a fifth byte B4 may be assigned information corresponding to

$$\text{?}$$

$$\text{?} \text{indicates text missing or illegible when filed}$$

and a sixth byte B5 and a seventh byte B6 may be assigned information corresponding to g_{coil,Tx}. Here, bits b7 to b0 of a first byte B0 of the PLAP packet may be reserved bits that may be assigned information corresponding to conditions of the z-distance and V_{RECT} to be applied to

$$\text{?} and \text{?} .$$

$$\text{?} \text{indicates text missing or illegible when filed}$$

Here, the information corresponding to the condition of the z-distance may be 0 when the z-distance is 0 mm and 1 when the z-distance is 2 mm. Further, the information corresponding to the condition of V_{RECT} may be 0 when V_{RECT} is 12V, 1 when V_{RECT} is 14V, and a value greater than 1 if V_{RECT} may exceed 14V.

Further, when receiving the scaling factors and MPLA coefficients from the receiver, the transmitter may store g_{coil,Rx} and g_{coil,Tx} corresponding to the scaling factors, and store

$$( {g}_{{FM}_{z = 0}^{12}} , {g}_{FM , {DC}_{z = 0}^{12}} , {α}_{{FM}_{z = 0}^{12}}^{GR} , {α}_{FM , {DC}_{z = 0}^{12}}^{GR} ) ,$$

$$( {g}_{{FM}_{z = 0}^{14}} , {g}_{FM , {DC}_{z = 0}^{14}} , {α}_{{FM}_{z = 0}^{14}}^{GR} , {α}_{FM , {DC}_{z = 0}^{14}}^{GR} ) ,$$

$$( {g}_{{FM}_{z = 0}^{Vmax}} , {g}_{FM , {DC}_{z = 0}^{Vmax}} , {α}_{{FM}_{z = 0}^{Vmax}}^{GR} , {α}_{FM , {DC}_{z = 0}^{Vmax}}^{GR} ) ,$$

$$( {g}_{{FM}_{z = 2}^{12}} , {g}_{FM , {DC}_{z = 2}^{12}} , {α}_{{FM}_{z = 2}^{12}}^{GR} , {α}_{FM , {DC}_{z = 2}^{12}}^{GR} ) ,$$

$$( {g}_{{FM}_{z = 2}^{14}} , {g}_{FM , {DC}_{z = 2}^{14}} , {α}_{{FM}_{z = 2}^{14}}^{GR} , {α}_{FM , {DC}_{z = 2}^{14}}^{GR} ) , and$$

$$( {g}_{{FM}_{z = 2}^{Vmax}} , {g}_{FM , {DC}_{z = 2}^{Vmax}} , {α}_{{FM}_{z = 2}^{Vmax}}^{GR} , {α}_{FM , {DC}_{z = 2}^{Vmax}}^{GR} )$$

as sets of scaling factors and MPLA coefficients. Meanwhile, the receiver may transmit information corresponding to V_{RECT} to the receiver using a PLA packet (in some cases, the PLA packet transmitted from the receiver to the transmitter may be referred to as a third packet). Here, the information corresponding to V_{RECT} may be information for assisting in selection of coefficients (specifically, a set of scaling factors and MPLA coefficients) used to estimate P_{FM}, and may be 0 when V_{RECT} is 12V, 1 when V_{RECT} is 14V, and a value greater than 1 if V_{RECT} may exceed 14V. The receiver may assign the information corresponding to V_{RECT} to reserved bits of the PLA packet. The PLA packet may consist of 5 bytes, where bits b4 to b0 of the first byte B0 may correspond to the reserved bits.

Further, the transmitter may select one of the sets of scaling factors and MPLA coefficients

$$( i . e . , \{ \text{?} , \text{?} , \text{?} , \text{?} \} ( i = 0 , 2 mm , {V}_{RECT} = 12 , 14 , … , {V}_{max} V ) )$$

$$\text{?} \text{indicates text missing or illegible when filed}$$

with reference to the determined coupling condition and the information assigned to the reserved bits of the PLA packet transmitted from the transmitter. For example, if the determined coupling condition corresponds to the first level (or high level) (i.e., kₑₛₜ is greater than or equal to 0.81×αₖₜₕ) and the information assigned to the reserved bits is 0 (i.e., V_{RECT} is 12V), the transmitter may select

$$( {g}_{{FM}_{z = 0}^{12}} , {g}_{FM , {DC}_{z = 0}^{12}} , {α}_{{FM}_{z = 0}^{12}}^{GR} , {α}_{FM , {DC}_{z = 0}^{12}}^{GR} )$$

among the sets of scaling factors and MPLA coefficients as the set of scaling factors and MPLA coefficients for estimating P_{FM}. As another example, if the determined coupling condition corresponds to the second level (or low level) (i.e., kₑₛₜ is less than 0.81×αₖₜₕ) and the information assigned to the reserved bits is 1 (i.e., V_{RECT} is 14V), the transmitter may select

$$( {g}_{{FM}_{z = 2}^{14}} , {g}_{FM , {DC}_{z = 2}^{14}} , {α}_{{FM}_{z = 2}^{14}}^{GR} , {α}_{FM , {DC}_{z = 2}^{14}}^{GR} )$$

among the sets of scaling factors and MPLA coefficients as the set of scaling factors and MPLA coefficients for estimating P_{FM}. Here, according to the transmitter's selection, the z-distance may be determined on the basis of kₑₛₜ, specifically as 0 mm in response to kₑₛₜ being greater than or equal to 0.81×αₖₜₕ, and as 2 mm in response to kₑₛₜ being less than 0.81×αₖₜₕ.

Further, the transmitter may estimate P_{FM} with reference to the selected set of scaling factors and MPLA coefficients (i.e., information acquired regarding the z-distance and V_{RECT}). This may also be described as the receiver causing P_{FM} to be estimated by the transmitter. Here, P_{FM} may be estimated from a relationship equation

$$\text{?} = \text{?} {I}_{Tx}^{2} + \text{?} .$$

$$\text{?} \text{indicates text missing or illegible when filed}$$

Meanwhile, the transmitter may estimate P_{coil loss,Tx} in addition to P_{FM}, and the receiver may estimate P_{coil loss, Rx}.

Although the present invention has been described above in terms of specific items such as detailed elements as well as the limited embodiments and the drawings, they are only provided to help more general understanding of the invention, and the present invention is not limited to the above embodiments. It will be appreciated by those skilled in the art to which the present invention pertains that various modifications and changes may be made from the above description.

Therefore, the spirit of the present invention shall not be limited to the above-described embodiments, and the entire scope of the appended claims and their equivalents will fall within the scope and spirit of the invention.

1. A method for power loss accounting, the method comprising the steps of:
acquiring information on at least one of a distance between a wireless power transmitter and a wireless power receiver and a rectified voltage of the wireless power receiver; and
estimating power loss due to friendly metal with reference to the acquired information.

2. The method of claim 1, wherein at least one of the distance and the rectified voltage functions as a variable for estimating the power loss.

3. The method of claim 1, wherein the distance is determined on the basis of a coupling coefficient.

4. The method of claim 3, wherein the distance is determined as a first value in response to the coupling coefficient being greater than or equal to a reference value, and as a second value in response to the coupling coefficient being less than the reference value.

5. The method of claim 3, wherein a first packet transmitted to the wireless power receiver includes information corresponding to the coupling coefficient.

6. The method of claim 1, wherein a second packet transmitted from the wireless power receiver includes information corresponding to a coefficient used to estimate the power loss and a condition to be applied to the coefficient.

7. The method of claim 1, wherein a third packet transmitted from the wireless power receiver includes information for assisting in selection of a coefficient used to estimate the power loss.

8. The method of claim 1, wherein a coefficient used to estimate the power loss is stored in the wireless power receiver, and the coefficient is dependent on at least one of the distance and the rectified voltage.

9. A wireless power transmitter, comprising:
an acquisition unit configured to acquire information on at least one of a distance between the wireless power transmitter and a wireless power receiver and a rectified voltage of the wireless power receiver; and
an estimation management unit configured to estimate power loss due to friendly metal with reference to the acquired information.

10. A method for power loss accounting, the method comprising the steps of:
acquiring information on at least one of a distance between a wireless power transmitter and a wireless power receiver and a rectified voltage of the wireless power receiver; and
causing power loss due to friendly metal to be estimated with reference to the acquired information.

11. The method of claim 10, wherein at least one of the distance and the rectified voltage functions as a variable for estimating the power loss.

12. The method of claim 10, wherein the distance is determined on the basis of a coupling coefficient.

13. The method of claim 12, wherein the distance is determined as a first value in response to the coupling coefficient being greater than or equal to a reference value, and as a second value in response to the coupling coefficient being less than the reference value.

14. The method of claim 12, wherein a first packet transmitted to the wireless power receiver includes information corresponding to the coupling coefficient.

15. The method of claim 10, wherein a second packet transmitted from the wireless power receiver includes information corresponding to a coefficient used to estimate the power loss and a condition to be applied to the coefficient.

16. The method of claim 10, wherein a third packet transmitted from the wireless power receiver includes information for assisting in selection of a coefficient used to estimate the power loss.

17. The method of claim 10, wherein a coefficient used to estimate the power loss is stored in the wireless power receiver, and the coefficient is dependent on at least one of the distance and the rectified voltage.

18. A wireless power receiver, comprising:
an acquisition unit configured to acquire information on at least one of a distance between a wireless power transmitter and the wireless power receiver and a rectified voltage of the wireless power receiver; and
an estimation management unit configured to cause power loss due to friendly metal to be estimated with reference to the acquired information.
